(19) United States
(12) Patent Application Publication
(10) Pub. No.: US 2026/0344203 A1
(43) Pub. Date: Oct. 29, 2026

(54) DISPLAY DEVICE

(71) Applicant: LG Display Co., Ltd., Seoul (KR)

(72) Inventors: Sunggon HONG, Paju-si (KR); Minsuk KONG, Paju-si (KR)

(21) Appl. No.: 19/655,867

(22) Filed: Apr. 23, 2026

(30) Foreign Application Priority Data
Apr. 29, 2025 (KR) 10-2025-0056062

(51) Int. Cl. H10K 59/124; H10K 59/122; H10K 59/80

(52) U.S. Cl. CPC H10K 59/124; H10K 59/122; H10K 59/80515; H10K 59/8731; H10K 59/8792

(57) ABSTRACT

A display device includes a substrate in which a light-emitting area and a non-light-emitting area surrounding the light-emitting area are defined, an insulating layer disposed on the substrate, a first electrode directly disposed on the insulating layer of the light-emitting area, an organic layer on the first electrode, a second electrode on the organic layer, a black matrix of the non-light-emitting area on the second electrode, and a color filter of the light-emitting area on the second electrode, wherein the insulating layer includes an insulating pattern recessed from an upper surface thereof.

### CROSS REFERENCE TO RELATED APPLICATION

Pursuant to 35 U.S.C. § 119(a), the present application claims the benefit of an earlier filing date and right of priority to Korean Patent Application No. 10-2025-0056062, filed Apr. 29, 2025, the entire contents of which is incorporated herein for all purposes by this reference.

### TECHNICAL FIELD

The present specification relates to a display device.

### BACKGROUND

As the information society develops, various demands for display devices for displaying images are increasing, and various types of display devices, such as liquid crystal display (LCD) devices, organic light-emitting diode (OLED) display devices, etc., are utilized.

### SUMMARY

According to one implementation, there is provided a display device including a substrate in which a light-emitting area and a non-light-emitting area surrounding the light-emitting area are defined, an insulating layer disposed on the substrate, a first electrode directly disposed on the insulating layer of the light-emitting area, an organic layer on the first electrode, a second electrode on the organic layer, a black matrix of the non-light-emitting area on the second electrode, and a color filter of the light-emitting area on the second electrode, wherein the insulating layer includes an insulating pattern recessed from an upper surface thereof.

According to another implementation, there is provided a display device including a substrate in which a first sub-pixel including a first light-emitting area and a non-light-emitting area, and a second sub-pixel including a second light-emitting area and a non-light-emitting area are defined, a thin-film transistor layer on the substrate, a first protective layer on the thin-film transistor layer, a second protective layer on the first protective layer, a third protective layer on the second protective layer, and a first electrode directly disposed on the third protective layer, wherein the third protective layer includes an insulating pattern concavely recessed in the third protective layer from an upper surface thereof, the first protective layer includes at least one first pattern recessed in the first protective layer in a thickness direction and filled with the second protective layer, the second protective layer includes a plurality of second patterns recessed in the second protective layer in the thickness direction and filled with the third protective layer, the at least one first pattern and the plurality of second patterns are disposed in each of the first light-emitting area and the second light-emitting area, and a width of the first pattern is greater than a width of the second pattern.

According to still another implementation, there is provided a display device including a substrate in which a first sub-pixel including a first light-emitting area and a non-light-emitting area and a second sub-pixel including a second light-emitting area and the non-light-emitting area are defined, a thin-film transistor layer including a transistor including a semiconductor layer, a gate electrode, an input electrode, and an output electrode on the substrate, and an insulating layer in contact with a first protective layer with the input electrode interposed therebetween, the first protective layer on the thin-film transistor layer, a second protective layer on the first protective layer, and a first electrode directly disposed on the second protective layer, wherein the second protective layer includes an insulating pattern recessed in the second protective layer from an upper surface thereof, the insulating layer includes at least one first pattern recessed in the insulating layer in a thickness direction and filled with the first protective layer, the first protective layer includes a plurality of second patterns recessed in the first protective layer in the thickness direction and filled with the second protective layer, the at least one first pattern and the plurality of second patterns are disposed in each of the first light-emitting area and the second light-emitting area, and a width of the first pattern is greater than a width of the second pattern.

Detailed matters of other implementations are included in the detailed description and accompanying drawings.

### BRIEF DESCRIPTION OF THE DRAWINGS

FIG. 1 is a plan view of a display device according to one implementation.

FIG. 2 is a cross-sectional view illustrating a bent state of the display panel according to FIG. 1.

FIG. 3 is a cross-sectional view of the display panel according to one implementation.

FIG. 4 is a cross-sectional view of a display panel according to another implementation.

FIG. 5 is a cross-sectional view of a display panel according to still another implementation.

FIG. 6 is a plan view of a display panel according to yet another implementation.

FIG. 7 is a cross-sectional view along lines A-A’ and B-B’ in FIG. 6.

FIG. 8 is an enlarged cross-sectional view of a thin-film transistor layer in FIG. 7.

FIG. 9 is a cross-sectional view of a touch part according to FIG. 7.

FIG. 10 is a cross-sectional view of the display panel according to yet another implementation.

FIG. 11 is a cross-sectional view of a display panel according to yet another implementation.

FIG. 12 is a cross-sectional view of a display panel according to yet another implementation.

FIG. 13 is a cross-sectional view of a display panel according to yet another implementation.

FIG. 14 is an enlarged cross-sectional view of area Q1 in FIG. 13.

### DETAILED DESCRIPTION

A display device includes a plurality of pixels and a plurality of switching elements for driving and controlling the pixels.

Various implementations of the present specification are also directed to providing a display device capable of preventing external light reflection (or surface reflection).

Various implementations of the present specification are also directed to providing a display device capable of collecting internally reflected light among external light.

Various implementations of the present specification are also directed to providing a display device capable of preventing light incident to a lower portion of a first electrode or light emitted from a light-emitting part and re-incident on the lower portion of the first electrode from being emitted to the outside.

Various implementations of the present specification are also directed to providing a display device capable of preventing deterioration of image quality caused by a separation distance between a side surface of a bank and a side surface of a black matrix or a viewing angle.

Various implementations of the present specification are also directed to providing a display device capable of scattering light reflected from a first electrode among external light and allowing the scattered light to be absorbed through a black matrix or a color filter.

Various implementations of the present specification are also directed to providing a display device with low reflection and low power.

Various implementations of the present specification are also directed to providing a display device which may have improved flexibility and may be applied to foldable products in which a display area is folded.

Objects of the present specification are not limited to the above objects, and other technical objects may be inferred from the following implementations.

Hereinafter, various implementations will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the specification, when a certain component (or an area, a layer, a portion, etc.) is described as “on,” “connected,” or “coupled to” another component, it means that the certain component may be directly connected/coupled to another component or still another component may be disposed therebetween.

The term “and/or” includes all one or more combinations that may be defined by the associated configurations.

Terms such as “first,” “second,” and the like may be used to describe various components, but the components are not limited by the terms. The terms are used only for the purpose of distinguishing one component from another. For example, a first component may be referred to as a second component, and similarly, the second component may also be referred to as the first component without departing from the scopes of various implementations. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the example term “below” may include both downward and upward directions.

It should be understood that terms such as “includes” or “has” are intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various implementations of the present specification may be coupled or combined partially or entirely, various technological interworking and driving are made possible, and various implementations may be implemented independently of each other or implemented together in an associated relationship.

Hereinafter, a display device of the present specification will be described with reference to the accompanying drawings and implementations as follows.

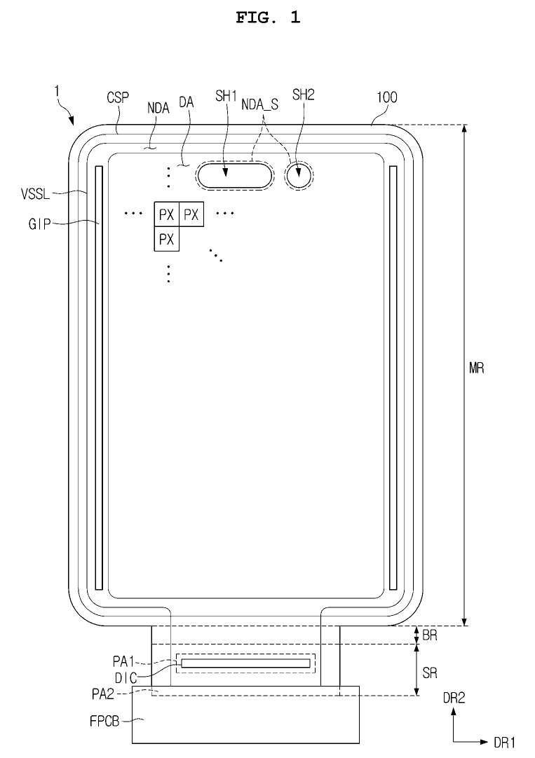

FIG. 1 is a plan view of a display device according to one implementation.

Referring to FIG. 1, a display device 1 according to one implementation may include a display panel 100. The display panel 100 may include a display area DA including a plurality of pixels PX and a non-display area NDA around the display area DA. The flat surface shape of the display area DA may have a rectangular shape. However, various implementations of the present specification are not limited thereto, and the flat surface shape of the display area DA may be a square, circular, elliptical, or other polygonal shapes. For example, the display area DA may have a rectangular shape with rounded corners, but is not limited thereto, and may also have a rectangular shape with angled corners.

In various implementations, a first direction DR1 and a second direction DR2 are different directions and intersect each other, for example, directions that intersect vertically in a plan view. In FIG. 1, the first direction DR1 may be generally the same as an extension direction of short edges of the display panel 100, and the second direction DR2 may be the same as an extension direction of long edges of the display panel 100. However, the directions described in various implementations should be understood as indicating relative directions, and various implementations are not limited to the described directions.

The display area DA may include short edges extending in the first direction DR1 and long edges extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH surrounded by the sensor non-display area NDA_S. The sensor holes SH1 and SH2 may be surrounded by the display area DA in a plan view. The sensor holes SH1 and SH2 may be, for example, two sensor holes as in FIG. 1, but various implementations of the present specification are not limited thereto. For example, the sensor hole may be provided as one sensor hole. The two sensor holes SH1 and SH2 may each include a sensor hole in which an infrared sensor is disposed and a sensor hole in which a camera sensor is disposed, but various implementations of the present specification are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S.

In some implementations, the sensor holes SH1 and SH2 are not disposed, and an infrared sensor or a camera sensor may be disposed in the display area DA. In this case, the number of pixels PX per area of the display area DA in which the infrared sensor or the camera sensor is disposed may be less than the number of pixels PX per area of the display area DA in which the infrared sensor or the camera sensor is not disposed. That is, the display area DA in which the infrared sensor or the camera sensor is disposed may further include a transmissive area.

A gate driving unit GIP may be disposed in the non-display area NDA positioned at the one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be positioned outside the gate driving unit GIP on the non-display area NDA, and disposed to surround the display area DA.

The non-display area NDA positioned at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 positioned at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driver DIC and the printed circuit board FPCB may be disposed in each of the first pad area PA1 and the second pad area PA2. A plurality of pads connected to the data driving unit DIC and the printed circuit board FPCB may be disposed in each of the first pad area PA1 and the second pad area PA2. The data driving unit DIC may be configured, for example, in the form of a driving chip (IC), but is not limited thereto. In one implementation, a case in which the data driving unit DIC is disposed by a chip on plastic method in which the data driving unit DIC is directly mounted on the display panel 100 is described, but various implementations of the present specification are not limited thereto, and the data driving unit DIC may be disposed by a chip on glass or chip on film method.

The display panel 100 according to one implementation may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, various implementations of the present specification are not limited thereto, and a part of the crack sensing pattern CSP may not be disposed in the non-display area NDA of the other side of the display area DA in the second direction DR2.

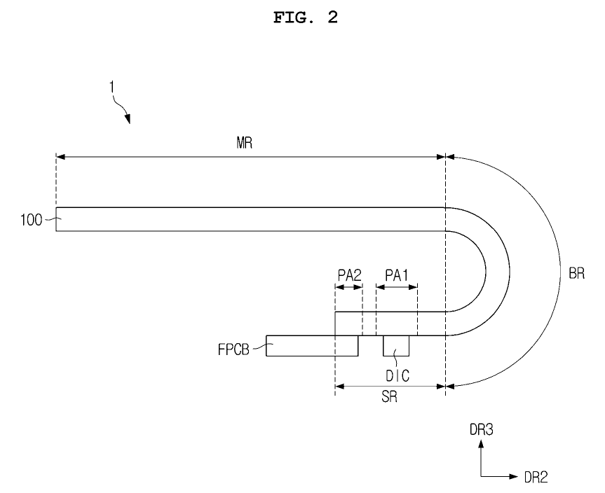

FIG. 2 is a cross-sectional view illustrating a bent state of the display panel according to FIG. 1.

Referring to FIG. 2, the bending region BR of the display panel 100 of the display device 1 according to one implementation may be bent in a thickness direction (or a third direction DR3). Accordingly, the main region MR and the sub-region SR may overlap each other in the thickness direction. The display panel 100 may be bent such that a lower surface of the main region MR faces an upper surface of the sub-region SR. The printed circuit board FPCB may be attached to an end portion of the sub-region SR.

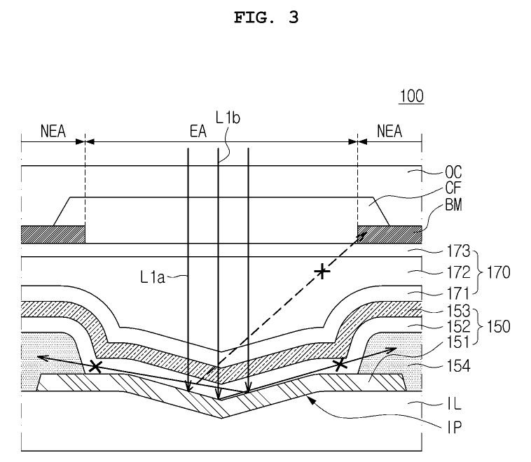

FIG. 3 is a cross-sectional view of the display panel according to one implementation.

Referring to FIG. 3, the display panel 100 according to one implementation may include an insulating layer IL, a light-emitting part 150 on the insulating layer IL, an encapsulation part 170 on the light-emitting part 150, a black matrix BM on the encapsulation part 170, a color filter CF on the black matrix BM, and a planarization layer OC on the color filter CF.

The insulating layer IL may include an organic or inorganic insulation material. An upper surface of the insulating layer IL may have a recess IP in a light-emitting area EA. The recess IP may be formed by recessing the insulating layer IL in a thickness direction from the upper surface of the insulating layer IL, as illustrated in FIG. 3. A width of the recess IP may increase from the bottom to the top. Conversely, the width of the recess IP may decrease from the top to the bottom. For example, a cross-sectional shape of the recess IP may have a V shape.

The light-emitting part 150 may be disposed on the insulating layer IL. The light-emitting part 150 may include a first electrode 151, an organic layer 152, and a second electrode 153.

The first electrode 151 may be disposed on the insulating layer IL. The first electrode 151 may be directly disposed on the insulating layer IL. Since the first electrode 151 is directly disposed on the insulating layer IL having the recess IP, the first electrode 151 may be disposed along the shape (e.g., a V shape) of the upper surface of the insulating layer IL, as illustrated in FIG. 3. For example, a central portion of the first electrode 151 may be positioned below an outer edge portion thereof. As such, different portions of the first electrode 151 may have different separation distances from an upper surface of the substrate disposed below the first electrode 151, e.g., the central portion of the first electrode 151 may have a smaller separation distance from the upper surface of the substrate, as compared to an outer edge portion of the first electrode 151.

The first electrode 151 may be an anode electrode, but various implementations of the present specification are not limited thereto. The first electrode 151 may be a reflective electrode that reflects light, but is not limited thereto. The first electrode 151 may include a metal material with high reflectivity, such as a stacked structure (Ti/Al/Ti) of aluminum (Al) and titanium (Ti), a stacked structure (ITO/Al/ITO) of aluminum (Al) and indium tin oxide (ITO), or an APC alloy, and may be formed of a single layer or multiple layers, but is not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. The organic layer 152 may be an organic light-emitting layer, an inorganic light-emitting layer, a quantum dot light-emitting layer, a micro light-emitting diode, a micro mini light-emitting diode, etc., but is not limited thereto.

The second electrode 153 may be disposed on the organic layer 152. The second electrode 153 may be a cathode electrode, but various implementations of the present specification are not limited thereto. The second electrode 153 may be a transparent electrode that transmits light, but is not limited thereto. For example, the second electrode 153 may include a transparent conductive material, such as ITO or IZO, or a metal that transmits visible light.

A bank 154 may be disposed to expose the first electrode 151. The bank 154 may define openings (or light-emitting areas EA1, EA2, and EA3) of the sub-pixels and may be disposed to cover an edge portion (or a periphery) of the first electrode 151. That is, non-light-emitting areas NEA may correspond to boundaries between adjacent sub-pixels.

The bank 154 may include a black-based material. For example, the bank 154 may be formed of a material containing black pigment, or an organic material, such as a benzocyclobutene resin, a polyimide resin, an acrylic resin, a photosensitive polymer, etc., but various implementations of the present specification are not limited thereto. When the bank 154 is formed of a material containing black pigment, black dye, etc., the bank 154 may be a black bank. When the bank 154 is formed of a material containing black pigment or black dye, it is possible to block external light or light reflected from the outside, thereby preventing surface reflection due to the external light. Although not illustrated, a spacer may be further disposed on the bank 154.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

The black matrix BM may be disposed on the encapsulation part 170. The black matrix BM may include a black-based material. For example, the black matrix BM may include a light-blocking material or a light-absorbing material. For example, the black matrix BM may be formed of a material including a black pigment, a black dye, etc. In some implementations, the black matrix BM may include a structure in which a red color filter, a green color filter, and a blue color filter are stacked.

The color filter CF may be disposed on the black matrix BM. The color filter CF may block a specific color from light emitted from the light-emitting area of each sub-pixel.

The planarization layer OC may further be disposed on the color filter CF. The planarization layer OC may planarize a step caused by the color filter CF. The planarization layer OC may contain an organic material, but various implementations of the present specification are not limited thereto.

As illustrated in FIG. 3, externally incident light L1a may be reflected by the first electrode 151 and absorbed by the black matrix BM or the color filter CF, and multiple externally incident light L1b may be absorbed by the adjacent bank 154. That is, in the display panel 100 according to one implementation, the first electrode 151 may have a concave central portion due to the insulating layer IL, thereby preventing external light reflection (or surface reflection). The first electrode 151 may be inclined along the upper surface of the insulating layer IL.

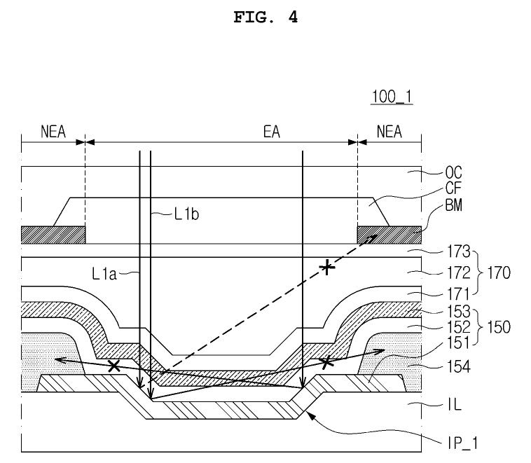

FIG. 4 is a cross-sectional view of a display panel according to another implementation.

Referring to FIG. 4, a cross-sectional shape of an insulating pattern IP_1 of a display panel 100_1 according to the present implementation is an inverted trapezoid, which differs from the display panel 100 according to FIG. 3. Even in the case of the display panel 100_1 according to the present implementation, the first electrode 151 may have a concave central portion due to the insulating layer IL, thereby preventing external light reflection (or surface reflection). More specifically, the central portion of the first electrode 151 may have a concave shape due to the insulating pattern IP_1 having an inverted trapezoidal shape. As described above with reference to FIG. 3, the light L1a and L1b may be absorbed by the black matrix BM or the bank 154.

Since the remaining parts have been described above with reference to FIG. 3, the detailed descriptions thereof will be omitted.

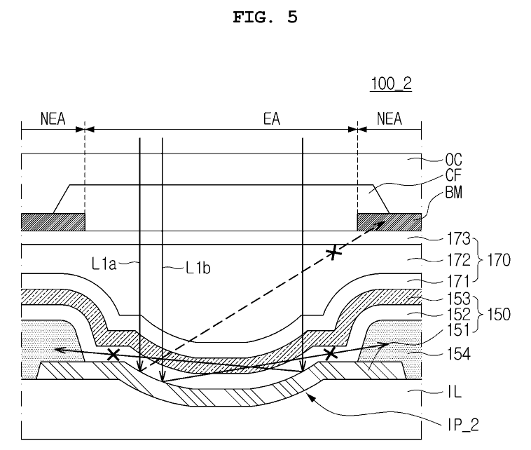

FIG. 5 is a cross-sectional view of a display panel according to still another implementation.

Referring to FIG. 5, a cross-sectional shape of an insulating pattern IP_2 of a display panel 100_2 according to the present implementation has a U shape, which differs from the display panel 100 according to FIG. 3.

Even in the case of the display panel 100_2 according to the present implementation, the first electrode 151 may have a concave central portion due to the insulating layer IL, thereby preventing external light reflection (or surface reflection).

Since the remaining parts have been described above with reference to FIG. 3, the detailed descriptions thereof will be omitted.

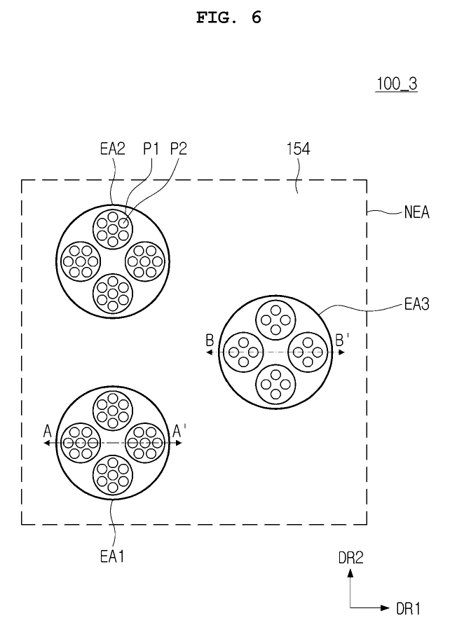

FIG. 6 is a plan view of a display panel according to yet another implementation.

Referring to FIG. 6, a display panel according to the present implementation may include light-emitting areas EA1, EA2, and EA3 and non-light-emitting areas NEA surrounding the light-emitting areas EA1, EA2, and EA3. For example, the pixel PX described above with reference to FIG. 1 may include a plurality of sub-pixels. The plurality of sub-pixels may include a first sub-pixel, a second sub-pixel, and a third sub-pixel. For example, the first sub-pixel may be a red sub-pixel, the second sub-pixel may be a green sub-pixel, and the third sub-pixel may be a blue sub-pixel. The first sub-pixel may include a first light-emitting area EA1 and the non-light-emitting area NEA, the second sub-pixel may include a second light-emitting area EA2 and the non-light-emitting area NEA, and the third sub-pixel may include a third light-emitting area EA3 and the non-light-emitting area NEA. That is, the non-light-emitting areas NEA may be disposed at the boundaries of adjacent sub-pixels.

Each of the light-emitting areas EA1, EA2, and EA3 illustrated in FIG. 6 may correspond to the opening of the bank 154 to be described below. That is, the bank 154 may not be disposed in the light-emitting areas EA1, EA2, and EA3. FIG. 6 illustrates that the planar shape of each of the light-emitting areas EA1, EA2, and EA3 in FIG. 6 is circular, but various implementations of the present specification are not limited thereto, and various planar shapes, such as rectangle, square, oval, etc., may be applied.

The display panel according to the present implementation may include a first pattern P1 and a second pattern P2 disposed in each of the light-emitting areas EA1, EA2, and EA3. A width of the first pattern P1 may be greater than a width of the second pattern P2, and one first pattern P1 may correspond to a plurality of second patterns P2. The one first pattern P1 may cover the plurality of second patterns P2. A width of the one first pattern P1 may be greater than the sum of the widths of the plurality of corresponding second patterns P2. For example, four first patterns P1 and seven second patterns P2 corresponding to each first pattern P1 (a total of 28) may be disposed in the first light-emitting area EA1, but various implementations of the present specification are not limited thereto, and the number of first patterns P1 and second patterns P2 disposed in the first light-emitting area EA1 is not limited thereto.

For example, four first patterns P1 and seven second patterns P2 corresponding to each first pattern P1 (a total of 28) may be disposed in the second light-emitting area EA2, but various implementations of the present specification are not limited thereto, and the number of first patterns P1 and second patterns P2 disposed in the second light-emitting area EA2 is not limited thereto.

The number of first patterns P1 disposed in the first light-emitting area EA1 may be the same as the number of first patterns P1 disposed in the second light-emitting area EA2, but various implementations of the present specification are not limited thereto.

The number of second patterns P2 corresponding to one first pattern P1 disposed in the first light-emitting area EA1 may be the same as the number of second patterns P2 corresponding to one first pattern P1 disposed in the second light-emitting area EA2, but various implementations of the present specification are not limited thereto.

In the third light-emitting area EA3, four first patterns P1 and four second patterns P2 corresponding to each first pattern P1 (a total of 16) may be disposed, but various implementations of the present specification are not limited thereto. For example, the number of first patterns P1 disposed in the third light-emitting area EA3 may be the same as the number of first patterns P1 disposed in the first light-emitting area EA1, but various implementations of the present specification are not limited thereto, and the number of first patterns P1 disposed in the third light-emitting area EA3 may be smaller than the number of first patterns P1 disposed in the first light-emitting area EA1.

In the third light-emitting area EA3, the number of second patterns P2 corresponding to one first pattern P1 may be smaller than the number of second patterns P2 corresponding to the one first pattern P1 in the first light-emitting area EA1 or the second light-emitting area EA2.

The first and second patterns P1 and P2 will be described in detail below.

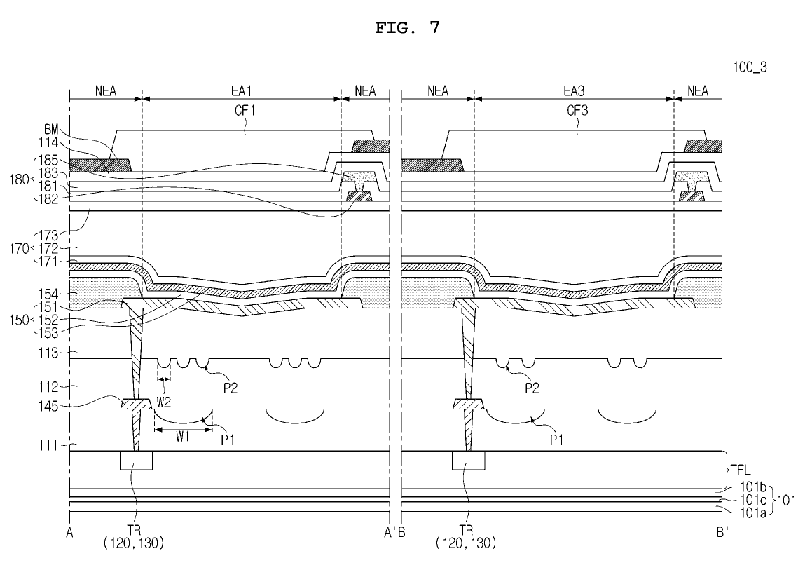

FIG. 7 is a cross-sectional view along lines A-A’ and B-B’ in FIG. 6. FIG. 7 illustrates that only cross sections of the first and third light-emitting areas EA1 and EA3 in FIG. 6 and the surrounding non-light-emitting areas NEA (i.e., the first sub-pixel and the third sub-pixel), but a cross section of the second sub-pixel may be the same as the cross section of the first sub-pixel. For convenience of description, the following description will focus on the cross-sections of the first and third sub-pixels.

Referring to FIG. 7, a display panel 100_3 according to the present implementation may include a substrate 101, a thin-film transistor layer TFL on the substrate 101, a first protective layer 111 on the thin-film transistor layer TFL and at least one additional protective layer on the first protective layer 111. In some implementations, the at least one additional protective layer can include a second protective layer 112 on the first protective layer 111. In some implementations, the at least one additional protective layer can further include a third protective layer 113 on the second protective layer 112. The display panel 100_3 can further include the light-emitting part 150, the encapsulation part 170, the touch part 180, a filter insulating layer 114, the black matrix BM, and first and third color filters CF1 and CF3.

The substrate 101 may include one or more plastic materials. For example, the substrate 101 may be a multi-substrate including a plurality of plastic materials, such as polyimide or the like, but is not limited thereto. For example, the substrate 101 may include a first substrate portion 101a and a second substrate portion 101b that include an organic material, and a third substrate portion 101c including an inorganic material, but the implementations of the present specification are not limited thereto.

The thin-film transistor layer TFL may include at least one thin-film transistor (TR), such as first thin-film transistor 120 and second thin-film transistor 130 (see FIG. 5 ) and at least one insulating layer. The thin-film transistor layer TFL will be described below with reference to FIG. 5.

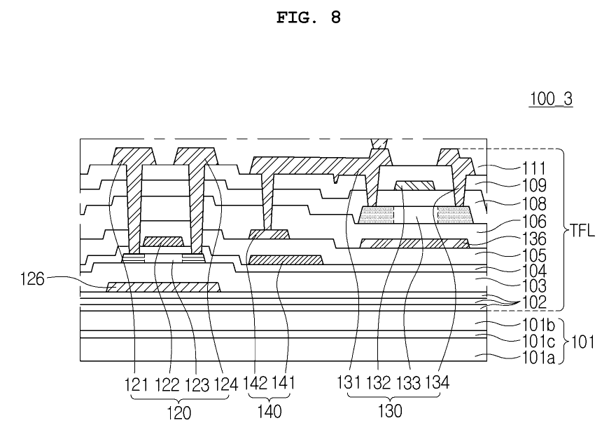

FIG. 8 is an enlarged cross-sectional view of a thin-film transistor layer in FIG. 7.

Referring to FIG. 8, the thin-film transistor layer TFL may include a buffer layer 102, a first thin-film transistor 120, a second thin-film transistor 130, a storage electrode 140, and insulating layers 103, 104, 105, 106, 108, and 109.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but is not limited thereto.

A first light-shielding layer 126 may be disposed on the buffer layer 102. The first light-shielding layer 126 can prevent light from transmitting a first semiconductor layer 123 of the first thin-film transistor 120. For example, the first semiconductor layer 123 may be disposed to overlap the first light-shielding layer 126.

A first insulating layer 103 may be disposed on the first light-shielding layer 126. The first insulating layer 103 may be formed of the same material as the buffer layer 102, but is not limited thereto.

The first thin-film transistor 120 may be disposed on the first insulating layer 103. The first thin-film transistor 120 may include a first input electrode 121, a first gate electrode 122, a first semiconductor layer 123, and a first output electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but is not limited thereto. The first semiconductor layer 123 may include a channel region, a source region, and a drain region.

A second insulating layer 104 may be disposed on the first semiconductor layer 123. The second insulating layer 104 may be formed of the same material as the first insulating layer 103, but is not limited thereto.

The first gate electrode 122 may be disposed on the second insulating layer 104. The first gate electrode 122 may be disposed on the second insulating layer 104 to overlap the channel region of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or compounds thereof. The first gate electrode 122 may be disposed together with a gate line.

A third insulating layer 105 may be disposed on the first gate electrode 122. The third insulating layer 105 may be formed of the same material as the first insulating layer 103 or the second insulating layer 104.

The first input electrode 121 and the first output electrode 124 may be disposed on the third insulating layer 105.

The first input electrode 121 and the first output electrode 124 may be electrically connected to the first semiconductor layer 123 via contact holes. The first input electrode 121 and the first output electrode 124 may be formed of a metal material.

The first input electrode 121 and the first output electrode 124 may be disposed together with the data line.

The storage electrode 140 may be disposed to be spaced apart from the first thin-film transistor 120. The storage electrode 140 may include a first storage electrode 141 and a second storage electrode 142.

The first storage electrode 141 may be disposed on the same layer as the first gate electrode 122 and may be made of the same material as the first gate electrode 122, but is not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance.

The second thin-film transistor 130 may be disposed to be spaced apart from the first thin-film transistor 120 and the storage electrode 140. The second thin-film transistor 130 may include a second input electrode 131, a second gate electrode 132, a second semiconductor layer 133, and a second output electrode 134.

A second light-shielding layer 136 may be disposed on the same layer as the second storage electrode 142.

For example, the second semiconductor layer 133 may be disposed to overlap the second light-shielding layer 136.

A fourth insulating layer 106 may be disposed on the second light-shielding layer 136. The fourth insulating layer 106 may be made of the same material as the first insulating layer 103, the second insulating layer 104, or the third insulating layer 105, but is not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as IGZO or the like, and a silicon-based semiconductor material, such as amorphous silicon, polycrystalline silicon, etc., but is not limited thereto.

A fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but is not limited thereto.

The second gate electrode 132 may be disposed on the fifth insulating layer 108.

The second gate electrode 132 may be made of the same material as the first gate electrode 122.

A sixth insulating layer 109 may be disposed on the second gate electrode 132. The sixth insulating layer 109 may be made of the same material as the first insulating layer 103, the second insulating layer 104, the third insulating layer 105, the fourth insulating layer 106, or the fifth insulating layer 108, but is not limited thereto.

The first input electrode 121, the first output electrode 124, the third storage electrode 143, the second input electrode 131, and the second output electrode 134 may be disposed on the sixth insulating layer 109.

The second input electrode 131 and the second output electrode 134 may be formed of the same material as the first input electrode 121 and the first output electrode 124 and disposed on the same layer.

The first thin-film transistor 120 may be a switching transistor, and the second thin-film transistor 130 may be a driving transistor, but various implementations of the present specification are not limited thereto.

The first protective layer 111 may be disposed on the first input electrode 121 and the first output electrode 124.

Referring back to FIG. 7, the first protective layer 111 may be disposed on the thin-film transistor layer TFL.

The first protective layer 111 may planarize an upper portion of the first thin-film transistor 120 and protect the first thin-film transistor 120. The first protective layer 111 may be made of an organic material.

A second protective layer 112 may be disposed on the first protective layer 111. The second protective layer 112 may be formed of the same material as the first protective layer 111, but is not limited thereto.

A connection electrode 145 may be disposed between the first protective layer 111 and the second protective layer 112.

The connection electrode 145 may electrically connect the thin-film transistor TR to the light-emitting part 150.

In some implementations, a third protective layer 113 may be disposed on the second protective layer 112 and the connection electrode 145. The third protective layer 113 may be made of the same material as the first protective layer 111, but is not limited thereto.

According to various implementations of the present specification, since diameters (or widths) of the lens shapes of the films below the first electrode (or the anode electrode) gradually decrease upward, the internally reflected light among external light may be collected at a single position.

More specifically, the first protective layer 111 and the second protective layer 112 according to one implementation may include patterns P1 and P2 recessed from upper surfaces thereof, respectively. The first protective layer 111 may include at least one first pattern P1, and the second protective layer 112 may include a plurality of second patterns P2. The first pattern P1 may recess the first protective layer 111 from the upper surface of the first protective layer 111, and the second pattern P2 may recess the second protective layer 112 from the upper surface of the second protective layer 112. Each of the first pattern P1 and the second pattern P2 may have a lens shape. The second protective layer 112 may fill the first pattern P1, and the third protective layer 113 may fill the second pattern P2.

The number of first patterns P1 may be, for example, two, but various implementations of the present specification are not limited thereto, and the number of the first patterns P1 may be one or three or more. However, the number of first patterns P1 in the first light-emitting area EA1 may be greater than or equal to the number of first patterns P1 in the third light-emitting area EA3. FIG. 4 exemplarily illustrates that two first patterns P1 are disposed in the first light-emitting area EA1 and two first patterns P1 are disposed in the third light-emitting area EA3.

A plurality of second patterns P2 may be disposed to correspond to one first pattern P1. For example, one first pattern P1 may cover the plurality of second patterns P2 disposed thereabove. The one first pattern P1 may completely cover the plurality of second patterns P2 disposed thereabove. The one first pattern P1 may overlap the plurality of second patterns P2. The first pattern P1 may have a first width W1, and the second pattern P2 may have a second width W2. The first width W1 may be greater than the second width W2.

According to the present implementation, since the width W1 of the first pattern P1 is greater than the width W2 of the second pattern P2 disposed thereabove and the first pattern P1 covers the plurality of second patterns P2, external light incident on a lower portion of the first electrode 151 or light emitted to the lower portion of the first electrode 151 among the light emitted from the light-emitting areas EA1 and EA3 can be easily collected upward (e.g., in a direction toward the first electrode 151).

In the present implementation, the number of second patterns P2 in the first light-emitting area EA1 may be greater than the number of second patterns P2 in the third light-emitting area EA3. That is, the number corresponding to one first pattern P1 may be greater in the first light-emitting area EA1 than in the third light-emitting area EA3.

In some implementations, the light-emitting part 150 may be disposed on the third protective layer 113. The light-emitting part 150 may include the first electrode 151, the organic layer 152, and the second electrode 153.

The first electrode 151 may be disposed on the third protective layer 113. The first electrode 151 may be electrically connected to the thin-film transistor TR via a contact hole formed in the third protective layer 113 and the second protective layer 112. The first electrode 151 may be an anode electrode, but various implementations of the present specification are not limited thereto. The first electrode 151 may be a reflective electrode that reflects light, but is not limited thereto. The first electrode 151 may include a metal material with high reflectivity, such as a stacked structure (Ti/Al/Ti) of aluminum (Al) and titanium (Ti), a stacked structure (ITO/Al/ITO) of aluminum (Al) and indium tin oxide (ITO), or an APC alloy, and may be formed of a single layer or multiple layers, but is not limited thereto.

The organic layer 152 may be disposed on the first electrode 151.

The second electrode 153 may be disposed on the organic layer 152.

The bank 154 may be disposed to expose the first electrode 151. The bank 154 may define openings (or light-emitting areas EA1, EA2, and EA3) of the sub-pixels and may be disposed to cover an edge portion (or a periphery) of the first electrode 151. That is, the non-light-emitting areas NEA may correspond to the boundaries between adjacent sub-pixels.

The bank 154 may include a black-based material. For example, the bank 154 may be formed of a material containing black pigment, or an organic material, such as a benzocyclobutene resin, a polyimide resin, an acrylic resin, a photosensitive polymer, etc., but various implementations of the present specification are not limited thereto. When the bank 154 is formed of a material containing black pigment, black dye, etc., the bank 154 may be a black bank. When the bank 154 is formed of a material containing black pigment or black dye, it is possible to block external light or light reflected from the outside, thereby preventing surface reflection due to the external light. Although not illustrated, a spacer may be further disposed on the bank 154.

The encapsulation part 170 may be disposed on the bank 154 or the light-emitting part 150. The encapsulation part 170 may include one or more insulating layers. For example, the encapsulation part 170 may include the first encapsulation layer 171, the second encapsulation layer 172 disposed on the first encapsulation layer 171, and the third encapsulation layer 173 on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

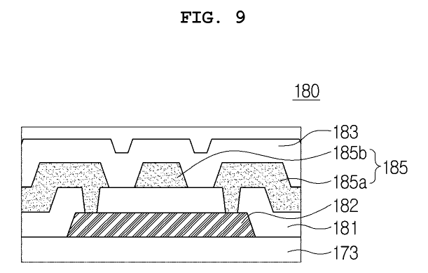

FIG. 9 is a cross-sectional view of a touch part according to FIG. 7.

Referring to FIGS. 7 and 9, the touch part 180 may be disposed on the encapsulation part 170. The touch part 180 may include a touch buffer layer 181, a first touch conductive layer, a bridge electrode 182, and a second touch conductive layer. A first touch conductive layer may be disposed on the third encapsulation layer 173. The first touch conductive layer may include the bridge electrode 182. The touch buffer layer 181 may be disposed on the first touch conductive layer. The touch buffer layer 181 can prevent a short circuit between touch electrodes. For example, the touch buffer layer 181 may contain an organic or inorganic material. The second touch conductive layer may be disposed on the touch buffer layer 181. The second touch conductive layer may include a sensor electrode 185. The touch insulating layer 183 may be disposed on the second touch conductive layer. The touch insulating layer 183 may include an organic material or an inorganic material. The bridge electrode 182 and the sensor electrode 185 may be disposed in the non-light-emitting area NEA, but various implementations of the present specification are not limited thereto.

The bridge electrode 182 and the sensor electrode 185 may be disposed at the boundaries between adjacent sub-pixels. For example, the bridge electrode 182 and the sensor electrode 185 may be disposed in the non-light-emitting areas NEA. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

In the second touch conductive layer, the sensor electrode 185 may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through contact holes formed in the touch buffer layer 181. For example, the first sensor electrode 185a and the bridge electrode 182 may extend in the first direction DR1 (see FIG. 1).

The sensor electrode 185 and the bridge electrode 182 may include a metallic material. For example, the sensor electrode 185 and the bridge electrode 182 may be made of titanium (Ti), nickel (Ni), aluminum (Al), or an alloy thereof and formed of a triple layer, such as titanium (Ti)/aluminum (Al)/titanium (Ti), but various implementations of the present specification are not limited thereto.

Referring back to FIG. 7, the filter insulating layer 114 may be disposed on the touch insulating layer 183. The filter insulating layer 114 may be formed of an inorganic insulation material, such as silicon nitride (SiNₓ) or silicon oxide (SiOₓ), but the implementations of the present specification are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. For example, a width of the black matrix BM may be smaller than a width of the bank 154.

For example, separation distances between an end of the black matrix BM and boundaries between the light-emitting areas EA1 and EA3 and the non-light-emitting area NEA may be longer than separation distances between an end of the bank 154 and the boundaries between the light-emitting areas EA1 and EA3 and the non-light-emitting area NEA. The end of the bank 154 may be aligned with the boundaries between the light-emitting areas EA1 and EA3 and the non-light-emitting area NEA, but various implementations of the present specification are not limited thereto. In the case of the display panel 100 according to one implementation, since the bank 154 may contain a black-based material and the separation distances between the end of the black matrix BM and the boundaries between the light-emitting areas EA1 and EA3 and the non-light-emitting area NEA may be longer than the separation distances between the end of the bank 154 and the boundaries between the light-emitting areas EA1 and EA3 and the non-light-emitting area NEA, light may be emitted upward with wider viewing angles as much as the separation spaces between the end of the black matrix BM and the boundaries between the light-emitting areas EA1 and EA3 and the non-light-emitting area NEA. Accordingly, it is possible to prevent a reduction in luminance due to the viewing angle. However, when the separation distances between the end of the black matrix BM and the boundaries between the light-emitting areas EA1 and EA3 and the non-light-emitting area NEA may be longer than the separation distances between the end of the bank 154 and the boundaries between the light-emitting areas EA1 and EA3 and the non-light-emitting area NEA and the bank 154 is formed of only a transparent material, externally incident light may be reflected by the bank 154, resulting in visible ring-shaped spots. However, in the display panel 100 according to one implementation, the externally incident light may be absorbed or blocked by the bank 154 including a black-based material, thereby preventing the occurrence of the ring-shaped spots.

The color filters CF1 and CF3 may be disposed on the black matrix BM. The color filters CF1 and CF3 may be disposed in the first and third sub-pixels, respectively, and may block a specific color from the light emitted from the light-emitting areas EA1 and EA3 of the sub-pixels. The first color filter CF1 may be provided to block light of the remaining colors excluding red (R) light. In this case, the first color filter CF1 may be provided as a red color filter. Although not illustrated, the second color filter may be configured to block light of colors other than green (G) light. In this case, the second color filter may be provided as a green color filter. A third color filter CF3 provided in the third sub-pixel may be provided to block light of other colors excluding blue (B) light. In this case, the third color filter CF3 may be provided as a blue color filter. However, various implementations of the present specification are not limited thereto.

For example, each of the color filters CF1 and CF3 may be in direct contact with side and upper surfaces of the black matrix BM. For example, each of the color filters CF1 and CF3 may be spaced apart from the boundary between adjacent sub-pixels, but various implementations of the present specification are not limited thereto, and the color filters CF1 and CF3 may overlap each other in the thickness direction.

A planarization layer may be further disposed on the color filters CF1 and CF3, but various implementations of the present specification are not limited thereto.

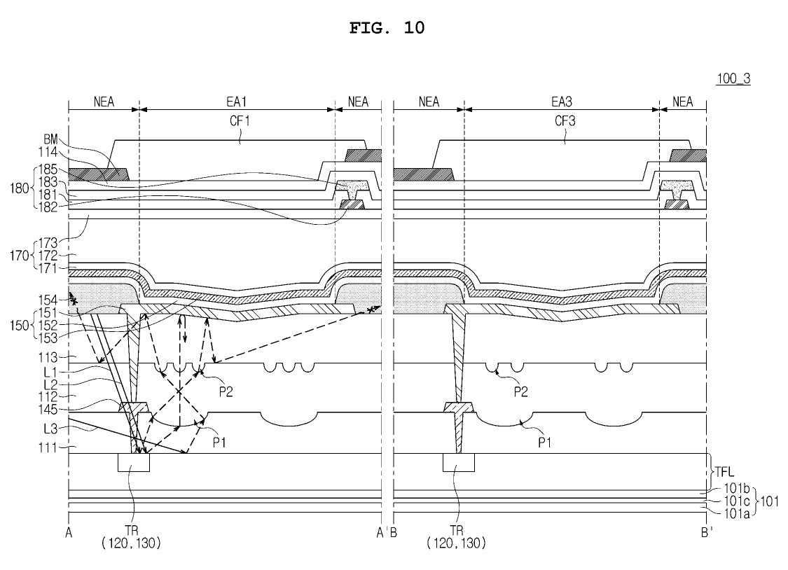

FIG. 10 is a cross-sectional view of the display panel according to yet another implementation.

Referring to FIG. 10, since diameters (or widths) of the lens shapes of the films below the first electrode 151 gradually decrease upward, internally reflected light among external light may be collected at a single position.

More specifically, light L1, L2, and L3 may be collected by the patterns P1 and P2, may travel upward, and may be reflected by the first electrode 151. The light L1 and L3 may be reflected by the first electrode 151, reflected at an interface between the second protective layer 112 and the third protective layer 113, and absorbed by the bank 154.

Since a width of the concave first pattern P1 of the first protective layer 111 is greater than a width of the concave second pattern P2 formed on the second protective layer 112, external light incident on the lower portion of the first electrode 151 or light emitted from the light emitting part 150 and re-incident on the lower portion of the first electrode 151 may be collected upward through the first pattern P1 and the second pattern P2. The light collected by the first pattern P1 and the second pattern P2 may be reflected back by the first electrode 151, scattered or refracted at the lower portion of the first electrode 151, and absorbed by the bank 154 containing a black-based material, thereby preventing reflection caused by external light.

Since the width of the concave first pattern P1 of the first protective layer 111 is greater than the width of the concave second pattern P2 formed on the second protective layer 112, the external light incident on the lower portion of the first electrode 151 or the light emitted from the light emitting part 150 and re-incident on the lower portion of the first electrode 151 can be prevented from being emitted to the outside.

In addition, in the display panel 100_3 according to the present implementation, the number of first patterns P1 or second patterns P2 for each sub-pixel may be controlled, thereby preventing deterioration of image quality caused by the separation distance between the side surface of the bank 154 and the side surface of the black matrix BM or the viewing angle.

More specifically, in the third light-emitting area EA3, the number of second patterns P2 corresponding to one first pattern P1 may be smaller than the number of second patterns P2 corresponding to the one first pattern P1 in the first light-emitting area EA1 or the second light-emitting area EA2. In the third light-emitting area EA3, the number of second patterns P2 corresponding to one first pattern P1 may be smaller than the number of second patterns P2 corresponding to the one first pattern P1 in the first light-emitting area EA1 or the second light-emitting area EA2.

In the case of the first and second sub-pixels including the first and second light-emitting areas EA1 and EA2, the luminance of light may be sensitive, compared to the third sub-pixel, to the separation distance between the side surface of the bank 154 and the side surface of the black matrix BM or to the viewing angle. Accordingly, in the case of the display panel 100_3 according to the present implementation, in the first and second sub-pixels in which the luminance of light is more sensitive, compared to the third sub-pixel, to the separation distance between the side surface of the bank 154 and the side surface of the black matrix BM or the viewing angle, it may be necessary to prevent the light incident on the lower portion of the first electrode 151 from being emitted to the outside. Accordingly, as described above, in the first and second light-emitting areas EA1 and EA2, the number of second patterns P2 corresponding to the one first pattern P1 may be greater than the number of second patterns P2 corresponding to the one first pattern P1 in the third light-emitting area EA3. Accordingly, it is possible to prevent the deterioration of image quality caused by the separation distance between the side surface of the bank and the side surface of the black matrix or the viewing angle by controlling the number of first or second patterns for each sub-pixel.

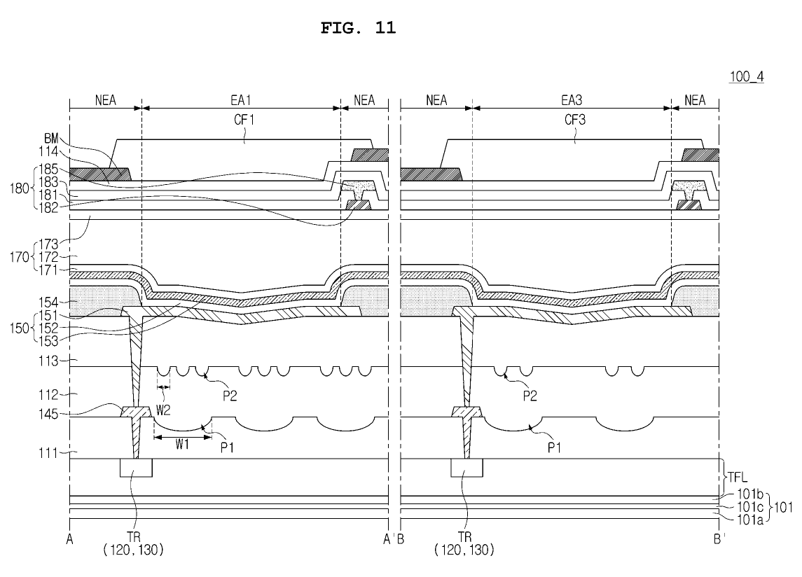

FIG. 11 is a cross-sectional view of a display panel according to yet another implementation.

Referring to FIG. 11, a display panel 100_4 according to the present implementation differs from the display panel 100_3 according to FIG. 7 in that the number of first patterns P1 in the first sub-pixel is greater than the number of first patterns P1 in the third sub-pixel.

More specifically, in the display panel 100_4 according to the present implementation, the number of first patterns P1 in the first sub-pixel may be greater than the number of first patterns P1 in the third sub-pixel.

Accordingly, as described above, in the first and second light-emitting areas EA1 and EA2, the number of second patterns P2 corresponding to the one first pattern P1 may be greater than the number of second patterns P2 corresponding to the one first pattern P1 in the third light-emitting area EA3. Accordingly, it is possible to prevent the deterioration of image quality due to the separation distance between the side surface of the bank and the side surface of the black matrix or the viewing angle by controlling the number of first or second patterns for each sub-pixel.

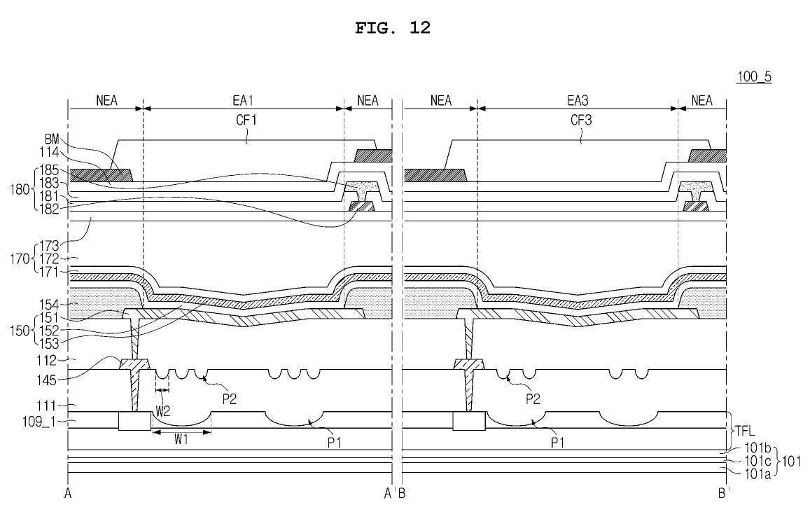

FIG. 12 is a cross-sectional view of a display panel according to yet another implementation.

Referring to FIG. 12, a display panel 100_5 according to the present implementation differs from the display panel 100_3 according to FIG. 7 in that the first pattern P1 is formed on a sixth insulating layer 109_1 and the second pattern P2 is formed on the first protective layer 111. In some implementations, there may not be a separate third protective layer 113.

Even in the present implementation, since a width of the concave first pattern P1 of the sixth insulating layer 109_1 is greater than a width of the concave second pattern P2 formed on the first protective layer 111, external light incident on the lower portion of the first electrode 151 or light emitted from the light emitting part 150 and re-incident on the lower portion of the first electrode 151 may be collected upward through the first pattern P1 and the second pattern P2. The light collected by the first pattern P1 and the second pattern P2 may be reflected back by the first electrode 151, scattered or refracted at the lower portion of the first electrode 151, and absorbed by the bank 154 containing a black-based material, thereby preventing reflection caused by external light.

It is possible to prevent the external light incident on the lower portion of the first electrode 151 or the light emitted from the light emitting part 150 and re-incident on the lower portion of the first electrode 151 from being emitted to the outside.

In addition, even in the display panel 100_5 according to the present implementation, the number of first patterns P1 or second patterns P2 for each sub-pixel may be controlled, thereby preventing the deterioration of image quality caused by the separation distance between the side surface of the bank 154 and the side surface of the black matrix BM or the viewing angle.

Since the remaining parts have been described above with reference to FIG. 7, the detailed descriptions thereof will be omitted.

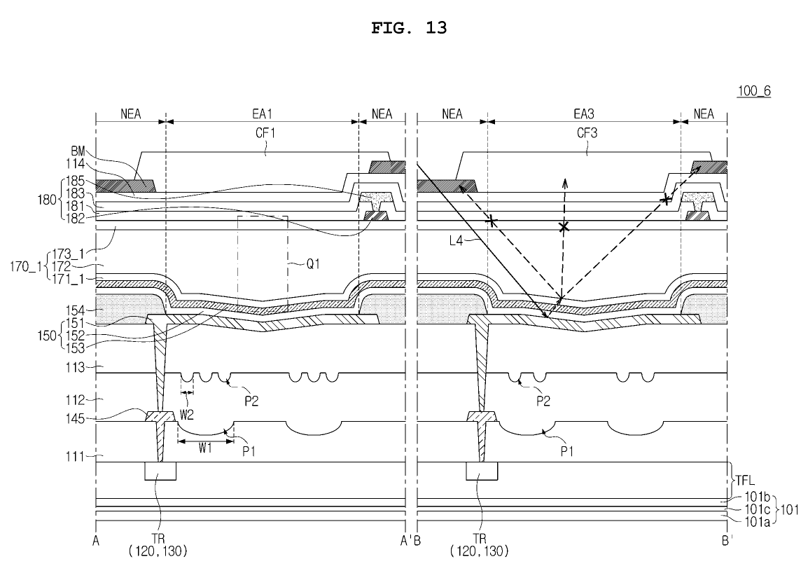

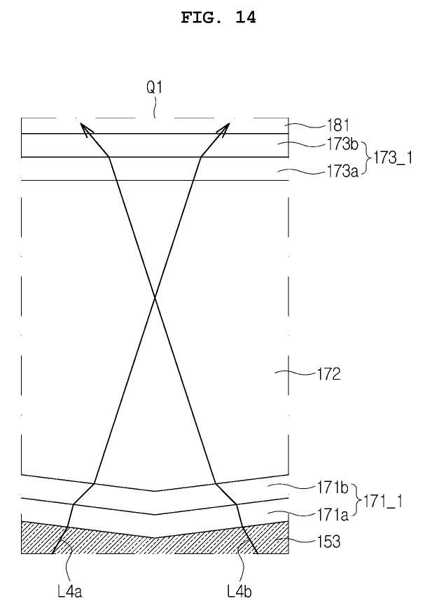

FIG. 13 is a cross-sectional view of a display panel according to yet another implementation. FIG. 14 is an enlarged cross-sectional view of area Q1 in FIG. 13.

Referring to FIGS. 13 and 14, a first encapsulation layer 171_1 or a third encapsulation layer 173_1 of a display panel 100_6 according to the present implementation differs from the display panel 100_3 according to FIG. 7 in that it may have a stacked structure of layers having different refractive indices.

More specifically, the first encapsulation layer 171_1 may include a high-refractive-index layer 171a and a low-refractive-index layer 171b on the high-refractive-index layer 171a, and the third encapsulation layer 173_1 may include a high-refractive-index layer 173a and a low-refractive-index layer 173b on the high-refractive-index layer 173a. FIG. 14 illustrates that the high-refractive-index layer is positioned below the low-refractive-index layer, but various implementations of the present specification are not limited thereto, and the low-refractive-index layer may be positioned below the high-refractive-index layer. In addition, FIG. 14 illustrates a single high-refractive-index layer and a single low-refractive-index layer, but two or more high-refractive-index layers and two or more low-refractive-index layers may be alternately stacked.

As illustrated in FIG. 13, external light L4 reflected by the first electrode 151 may be refracted and scattered by each of the first encapsulation layer 171_1 or the third encapsulation layer 173_1 that have a stacked structure of layers having different refractive indices, thereby reducing the intensity of light. Accordingly, the external light L4 having the reduced intensity may be absorbed by the black matrix BM or the color filter. Accordingly, the display panel 100_6 according to the present implementation can prevent reflection caused by external light and prevent external light incident on the display panel from being emitted to the outside.

As illustrated in FIG. 14, each of external light L4a and L4b may travel while being refracted at an interface between the high-refractive-index layer 171a and the low-refractive-index layer 171b, refracted at an interface between the low-refractive-index layer 171b and the second encapsulation layer 172, and refracted at an interface between the high-refractive-index layer 173a and the low-refractive-index layer 173b. As described above, the external light may be refracted and scattered in the first encapsulation layer 171_1 or the third encapsulation layer 173_1, thereby reducing the intensity of light and allowing it to become an optical path toward the black matrix BM.

Since the remaining parts have been described above with reference to FIG. 7, the detailed descriptions thereof will be omitted.

A display device according to various implementations of the present specification may be described as follows.

According to various implementations of the present specification, there is provided a display device including a substrate in which a light-emitting area and a non-light-emitting area surrounding the light-emitting area are defined, an insulating layer disposed on the substrate, a first electrode directly disposed on the insulating layer of the light-emitting area, an organic layer on the first electrode, a second electrode on the organic layer, a black matrix of the non-light-emitting area on the second electrode, and a color filter of the light-emitting area on the second electrode, in which the insulating layer includes an insulating pattern recessed from an upper surface thereof.

In the display device according to various implementations of the present specification, a width of the insulating pattern may increase upward.

In the display device according to various implementations of the present specification, a cross-sectional shape of the insulating pattern may have a V shape.

In the display device according to various implementations of the present specification, a cross-sectional shape of the insulating pattern may have an inverted trapezoidal shape.

In the display device according to various implementations of the present specification, a cross-sectional shape of the insulating pattern may have a U shape.

In the display device according to various implementations of the present specification, the first electrode may be inclined along an upper surface of the insulating layer.

In the display device according to various implementations of the present specification, a central portion of the first electrode may be disposed below an outer edge portion of the first electrode.

According to various implementations of the present specification, there is provided a display device including a substrate in which a first sub-pixel including a first light-emitting area and a non-light-emitting area, and a second sub-pixel including a second light-emitting area and a non-light-emitting area are defined, a thin-film transistor layer on the substrate, a first protective layer on the thin-film transistor layer, a second protective layer on the first protective layer, a third protective layer on the second protective layer, and a first electrode directly disposed on the third protective layer, in which the third protective layer includes an insulating pattern concavely recessed in the third protective layer from an upper surface thereof, the first protective layer includes at least one first pattern recessed in the first protective layer in a thickness direction and filled with the second protective layer, the second protective layer includes a plurality of second patterns recessed in the second protective layer in the thickness direction and filled with the third protective layer, the at least one first pattern and the plurality of second patterns are disposed in each of the first light-emitting area and the second light-emitting area, and a width of the first pattern is greater than a width of the second pattern.

In the display device according to various implementations of the present specification, the first pattern may overlap the plurality of second patterns.

In the display device according to various implementations of the present specification, the first pattern may completely cover the plurality of second patterns.

The display device according to various implementations of the present specification may further include a bank configured to cover the first electrode in the non-light-emitting area, and the bank may include a black-based material.

The display device according to various implementations of the present specification may further include a black matrix disposed in the non-light-emitting area on the first electrode, and a distance between a side surface of the bank and the first light-emitting area may be shorter than a distance between a side surface of the black matrix and the first light-emitting area.

The display device according to various implementations of the present specification may further include an organic layer on the first electrode, a second electrode on the organic layer, and an encapsulation part on the second electrode, in which the encapsulation part includes a first encapsulation layer and a third encapsulation layer, each of which includes an inorganic insulation material, and a second encapsulation layer disposed between the first encapsulation layer and the third encapsulation layer and having an organic material, and the first encapsulation layer or the third encapsulation layer may have a stacked structure of a low-refractive-index layer and a high-refractive-index layer.

In the display device according to various implementations of the present specification, the number of second patterns in the first light-emitting area may be greater than the number of second patterns in the second light-emitting area.

In the display device according to various implementations of the present specification, the number of first patterns in the first light-emitting area may be greater than the number of first patterns in the second light-emitting area.

According to various implementations of the present specification, there is provided a display device including a substrate in which a first sub-pixel including a first light-emitting area and a non-light-emitting area and a second sub-pixel including a second light-emitting area and the non-light-emitting area are defined, a thin-film transistor layer including a transistor including a semiconductor layer, a gate electrode, an input electrode, and an output electrode on the substrate, and an insulating layer in contact with a first protective layer with the input electrode interposed therebetween, the first protective layer on the thin-film transistor layer, a second protective layer on the first protective layer, and a first electrode directly disposed on the second protective layer, in which the second protective layer includes an insulating pattern recessed in the second protective layer from an upper surface thereof, the insulating layer includes at least one first pattern recessed in the insulating layer in a thickness direction and filled with the first protective layer, the first protective layer includes a plurality of second patterns recessed in the first protective layer in the thickness direction and filled with the second protective layer, the at least one first pattern and the plurality of second patterns are disposed in each of the first light-emitting area and the second light-emitting area, and a width of the first pattern is greater than a width of the second pattern.

In the display device according to various implementations of the present specification, the first pattern may overlap the plurality of second patterns, and the first pattern may completely cover the plurality of second patterns.

According to various implementations of the present specification, the insulating layer below the first electrode can include the concave pattern, thereby preventing external light reflection (or surface reflection).

According to various implementations of the present specification, since the diameters (or the widths) of the lens shapes of the films below the first electrode (or the anode electrode) gradually decrease upward, the internally reflected light among external light can be collected at a single position.

According to various implementations of the present specification, since the width of the concave first pattern of the first protective layer is greater than the width of the concave second pattern formed in the second protective layer, the external light incident on the lower portion of the first electrode, or the light emitted from the light-emitting part and re-incident on the lower portion of the first electrode can be collected upward through the first pattern and the second pattern. The light collected by the first pattern and the second pattern can be reflected back by the first electrode, scattered or refracted below the first electrode, and then absorbed by the bank containing a black-based material, thereby preventing reflection caused by external light.

According to various implementations of the present specification, since the width of the concave first pattern of the first protective layer is greater than the width of the concave second pattern formed in the second protective layer, the external light incident on the lower portion of the first electrode, or the light emitted from the light-emitting part and re-incident on the lower portion of the first electrode can be prevented from being emitted to the outside.

According to various implementations of the present specification, it is possible to prevent the deterioration of image quality caused by the separation distance between the side surface of the bank and the side surface of the black matrix or the viewing angle by controlling the number of first or second patterns for each sub-pixel.

According to various implementations of the present specification, by including the first encapsulation layer or the third encapsulation layer having the stacked structure of the high refractive index layer and the low refractive index layer, the light reflected from the first electrode among external light may be scattered and absorbed by the black matrix or the color filter, thereby preventing reflection caused by external light and preventing the external light incident on the display panel from being emitted to the outside.

According to various implementations of the present specification, the surface reflection of external light can be improved, thereby providing low-reflection display device and achieving low power consumption.

According to various implementations of the present specification, by omitting the polarizing part, the display device can have improved flexibility and can be applied to foldable products in which the display area is folded.

However, effects obtainable from the present specification are not limited to the above effects, and other effects that are not described will be able to be clearly understood by those skilled in the art to which the present specification pertains based on the following description.

Although various implementations of the present disclosure have been described with reference to the accompanying drawings, it will be understood by those skilled in the art that the above-described technical configuration of the present disclosure may be implemented in other specific forms without changing the technical spirit or essential features of the present disclosure. Accordingly, it should be understood that the above-described implementations are illustrative and not restrictive in all aspects. In addition, the scope of the present disclosure is described by the claims to be described below rather than the detailed description. In addition, the meaning and scope of the claims and all changed or modified forms derived from the equivalent concept should be construed as being included in the scope of the present disclosure.

What is claimed is:

1. A display device comprising:
a substrate in which a sub-pixel including a light-emitting area and a non-light-emitting area is defined;
a thin-film transistor layer on the substrate;
an insulating layer on the thin-film transistor layer;
a first protective layer on the insulating layer;
at least one additional protective layer on the first protective layer;
a first electrode disposed on the at least one additional protective layer; and
a bank which covers a periphery of the first electrode and has a black-based material,
wherein, in the light-emitting area, the at least one additional protective layer has a recess in an upper surface of the at least one additional protective layer.

2. The display device of claim 1, wherein an upper portion of the recess has a larger width than a lower portion of the recess.

3. The display device of claim 2, wherein a cross-sectional shape of the recess has a V shape, an inverted trapezoidal shape, or a U shape.

4. The display device of claim 1, wherein the first electrode is inclined along the upper surface of the at least one additional protective layer.

5. The display device of claim 1, wherein a central portion of the first electrode is disposed at a lower height than an outer edge portion of the first electrode.

6. The display device of claim 1, wherein different portions of the first electrode have different separation distances from an upper surface of the substrate.

7. The display device of claim 1, further comprising:
an organic layer on the first electrode;
a second electrode on the organic layer; and
a black matrix in the non-light-emitting area on the second electrode.

8. The display device of claim 7, wherein a distance between a side surface of the bank and the light-emitting area is shorter than a distance between a side surface of the black matrix and the light-emitting area.

9. The display device of claim 1, wherein the sub-pixel includes a first sub-pixel and a second sub-pixel,
wherein at least one additional protective layer includes (i) a second protective layer on the first protective layer and (ii) a third protective layer on the second protective layer,
wherein the recess is in an upper surface of the third protective layer,
wherein the first protective layer includes at least one first pattern concavely recessed in an upper surface thereof,
wherein the second protective layer includes a plurality of second patterns concavely recessed in an upper surface thereof,
wherein the at least one first pattern and the plurality of second patterns are disposed in each of a light-emitting area of the first sub-pixel and a light-emitting area of the second sub-pixel, and
a width of the first pattern is greater than a width of each of the plurality of second patterns.

10. The display device of claim 9, wherein the first pattern overlaps the plurality of second patterns.

11. The display device of claim 10, wherein the first pattern completely covers the plurality of second patterns.

12. The display device of claim 7, further comprising an encapsulation part between the second electrode and the black matrix, in which the encapsulation part includes a first encapsulation layer and a third encapsulation layer, each of which includes an inorganic insulation material, and a second encapsulation layer disposed between the first encapsulation layer and the third encapsulation layer and including an organic material, and the first encapsulation layer or the third encapsulation layer has a stacked structure of a low-refractive-index layer and a high-refractive-index layer.

13. The display device of claim 9, wherein a number of second patterns in the light-emitting area of the first sub-pixel is greater than a number of second patterns in the light-emitting area of the second sub-pixel.

14. The display device of claim 9, wherein a number of first patterns in a light-emitting area of the first sub-pixel is greater than a number of first patterns in a light-emitting area of the second sub-pixel.

15. The display device of claim 1, wherein the at least one additional protective layer includes a second protective layer on the first protective layer,
wherein the recess is in an upper surface of the second protective layer,
wherein the insulating layer includes at least one first pattern concavely recessed in the insulating layer in a thickness direction and filled with the first protective layer,
wherein the first protective layer includes the at least one first pattern concavely recessed in the first protective layer in the thickness direction and filled with the second protective layer, and a plurality of second patterns are disposed in each of a light-emitting area of a first sub-pixel and a light-emitting area of a second sub-pixel, and
wherein a width of the first pattern is greater than a width of each of the plurality of second patterns.

16. The display device of claim 15, wherein the first pattern overlaps the plurality of second patterns.

17. The display device of claim 16, wherein the first pattern completely covers the plurality of second patterns.

18. The display device of claim 15, further comprising:
an organic layer on the first electrode;
a second electrode on the organic layer;
a black matrix in the non-light-emitting area on the second electrode; and
an encapsulation part between the second electrode and the black matrix, in which the encapsulation part includes a first encapsulation layer and a third encapsulation layer, each of which includes an inorganic insulation material, and a second encapsulation layer disposed between the first encapsulation layer and the third encapsulation layer and including an organic material, and the first encapsulation layer or the third encapsulation layer has a stacked structure of a low-refractive-index layer and a high-refractive-index layer.

19. The display device of claim 15, wherein a number of second patterns in the light-emitting area of the first sub-pixel is greater than a number of second patterns in the light-emitting area of the second sub-pixel.

20. The display device of claim 15, wherein a number of first patterns in a light-emitting area of the first sub-pixel is greater than a number of first patterns in a light-emitting area of the second sub-pixel.
